(19) United States
(12) Patent Application Publication
(10) Pub. No.: US 2016/0333268 A1
(43) Pub. Date: Nov. 17, 2016

(54) Irregular Large Volume Semiconductor Coatings for Quantum Dots (QDs)

(71) Applicant: PACIFIC LIGHT TECHNOLOGIES CORP., Portland, OR (US)

(72) Inventors: Matthew J. Carillo, Portland, OR (US); Matthew Bertram, Portland, OR (US); Norbert Puetz, Ottawa (CA); Juanita N. Kurtin, Hillsboro, OR (US)

(21) Appl. No.: 15/112,397

(22) PCT Filed: Jan. 16, 2015
(86) PCT No.: PCT/US15/11720

§ 371 Date: Jul. 18, 2016

Related U.S. Application Data
(60) Provisional application No. 61/928,577, filed on Jan. 17, 2014.

(51) Int. Cl. C09K 11/88; H01L 33/50

(52) U.S. Cl. CPC C09K 11/883; H01L 33/504

(57) ABSTRACT

Irregular large volume semiconductor coatings for quantum dots (QDs) and the resulting quantum dot materials are described. In an example, a semiconductor structure includes a quantum dot structure having an outermost surface. A crystalline semiconductor coating is disposed on and completely surrounds the outermost surface of the quantum dot structure. The crystalline semiconductor coating has an irregular outermost geometry.

### CROSS-REFERENCE TO RELATED APPLICATIONS

This application claims the benefit of U.S. Provisional Application No. 61/928,577, filed Jan. 17, 2014, the entire contents of which are hereby incorporated by reference herein.

### TECHNICAL FIELD

Embodiments of the present invention are in the field of quantum dots and, in particular, irregular large volume semiconductor coatings for quantum dots (QDs).

### BACKGROUND

Quantum dots having a high photoluminescence quantum yield (PLQY) may be applicable as down-converting materials in down-converting nano-composites used in solid state lighting applications. Down-converting materials are used to improve the performance, efficiency and color choice in lighting applications, particularly light emitting diodes (LEDs). In such applications, quantum dots absorb light of a particular first (available or selected) wavelength, usually blue, and then emit light at a second wavelength, usually red or green.

### SUMMARY

Embodiments of the present invention include irregular large volume semiconductor coatings for quantum dots (QDs).

In an embodiment, a semiconductor structure includes a quantum dot structure having an outermost surface. A crystalline semiconductor coating is disposed on and completely surrounds the outermost surface of the quantum dot structure. The crystalline semiconductor coating has an irregular outermost geometry.

In an embodiment, a semiconductor structure includes a nanocrystalline core of a first semiconductor material. A nanocrystalline shell of a second semiconductor material different from the first semiconductor material is disposed on and surrounds the nanocrystalline core. A crystalline semiconductor coating of a third semiconductor material different from the first and second semiconductor materials is disposed on and completely surrounds the nanocrystalline shell. The crystalline semiconductor coating has an irregular outermost geometry.

In another embodiment, a lighting apparatus includes a housing structure and a light emitting diode supported within the housing structure. The lighting apparatus also includes a light conversion layer disposed above the light emitting diode. The light conversion layer includes a plurality of quantum dots. Each quantum dot includes a nanocrystalline core of a first semiconductor material. A nanocrystalline shell of a second semiconductor material different from the first semiconductor material is disposed on and surrounds the nanocrystalline core. A crystalline semiconductor coating of a third semiconductor material different from the first and second semiconductor materials is disposed on and completely surrounds the nanocrystalline shell. The crystalline semiconductor coating has an irregular outermost geometry.

In another embodiment, a lighting apparatus includes a substrate and a light emitting diode disposed on the substrate. The lighting apparatus also includes a light conversion layer disposed above the light emitting diode. The light conversion layer includes a plurality of quantum dots. Each quantum dot includes a nanocrystalline core of a first semiconductor material. A nanocrystalline shell of a second semiconductor material different from the first semiconductor material is disposed on and surrounds the nanocrystalline core. A crystalline semiconductor coating of a third semiconductor material different from the first and second semiconductor materials is disposed on and completely surrounds the nanocrystalline shell. The crystalline semiconductor coating has an irregular outermost geometry.

### BRIEF DESCRIPTION OF THE DRAWINGS

FIG. 1 is a representative transmission electron microscope (TEM) image showing an outer irregular coating grown on a quantum dot structure, in accordance with an embodiment of the present invention.

FIG. 2 is a representative transmission electron microscope (TEM) image showing an outer irregular coating grown on a quantum dot structure, in accordance with an embodiment of the present invention.

FIG. 3 is a representative transmission electron microscope (TEM) image showing an outer irregular coating grown on a quantum dot structure, in accordance with an embodiment of the present invention.

FIG. 4 is a plot showing representative temperature performance for irregularly coated quantum dots, in accordance with an embodiment of the present invention.

FIG. 5 is a plot showing representative climate chamber performance for irregularly coated quantum dots, in accordance with an embodiment of the present invention.

FIG. 6 is a plot showing relative red emission from an LED for irregularly coated quantum dots, in accordance with an embodiment of the present invention.

FIG. 7 illustrates a schematic of a cross-sectional view of a nano-crystalline core and nano-crystalline shell pairing with an irregular crystalline semiconductor layer formed thereon, in accordance with an embodiment of the present invention.

FIG. 8 illustrates operations in a reverse micelle approach to insulating a semiconductor structure having an irregular semiconductor coating thereon, in accordance with an embodiment of the present invention.

FIG. 9 illustrates a lighting device that includes a blue LED with a layer having a polymer matrix with a dispersion of irregularly coated quantum dots therein, in accordance with an embodiment of the present invention.

FIG. 10 illustrates a cross-sectional view of a lighting device with a layer having a polymer matrix with a dispersion of irregularly coated quantum dots therein, in accordance with an embodiment of the present invention.

FIG. 11 illustrates a cross-sectional view of a lighting device with a layer having a polymer matrix with a dispersion of irregularly coated quantum dots therein, in accordance with another embodiment of the present invention.

FIG. 12 illustrates a cross-sectional view of a lighting device with a layer having a polymer matrix with a dispersion of irregularly coated quantum dots therein, in accordance with another embodiment of the present invention.

FIG. 13 illustrates a cross-sectional view of a lighting device with a layer having a polymer matrix with a dispersion of irregularly coated quantum dots therein, in accordance with another embodiment of the present invention.

FIGS. 14A-14C illustrate cross-sectional views of various configurations for lighting devices with a layer having a polymer matrix with a dispersion of irregularly coated quantum dots therein, in accordance with another embodiment of the present invention.

### DETAILED DESCRIPTION

Irregular large volume semiconductor coatings for quantum dots (QDs) and the resulting quantum dot materials are described herein. In the following description, numerous specific details are set forth, such as specific semiconductor coating materials, and quantum dot geometries and efficiencies, in order to provide a thorough understanding of embodiments of the present invention. It will be apparent to one skilled in the art that embodiments of the present invention may be practiced without these specific details. In other instances, well-known related apparatuses, such as the host of varieties of applicable light emitting diodes (LEDs), are not described in detail in order to not unnecessarily obscure embodiments of the present invention. Furthermore, it is to be understood that the various embodiments shown in the figures are illustrative representations and are not necessarily drawn to scale.

One or more embodiments described herein are directed to semiconductor coatings for quantum dots. Certain embodiments may be directed to very stable high performance semiconductor quantum dot materials that include a seeded rod semiconductor structure (nanocrystalline core/shell pairing) coated with a thick layer of a third semiconductor material. The third semiconductor material coating has an appearance that is bumpy or spiky (irregular), although still crystalline. Such a configuration for a quantum dot structure allows for the addition of a relatively large amount of material without reducing the performance of the inner seeded rod structure.

To provide context, quantum dot structure such as quantum dot heterostructures (QDHs) may require protection in certain applications requiring higher, more reliable performance under the associated conditions of high incident intensity, high operating temperatures, and humidity. In accordance with an embodiment of the present invention, a QDH based on a nanocrystalline core of a first semiconductor material and a surrounding nanocrystalline shell of a second semiconductor material has a third semiconductor material coated there around. The third semiconductor material is applied as a coating that may provide an extra layer of protection for the quantum dot structure which results in a higher, more reliable performance under the conditions of high incident intensity, high operating temperatures, and humidity.

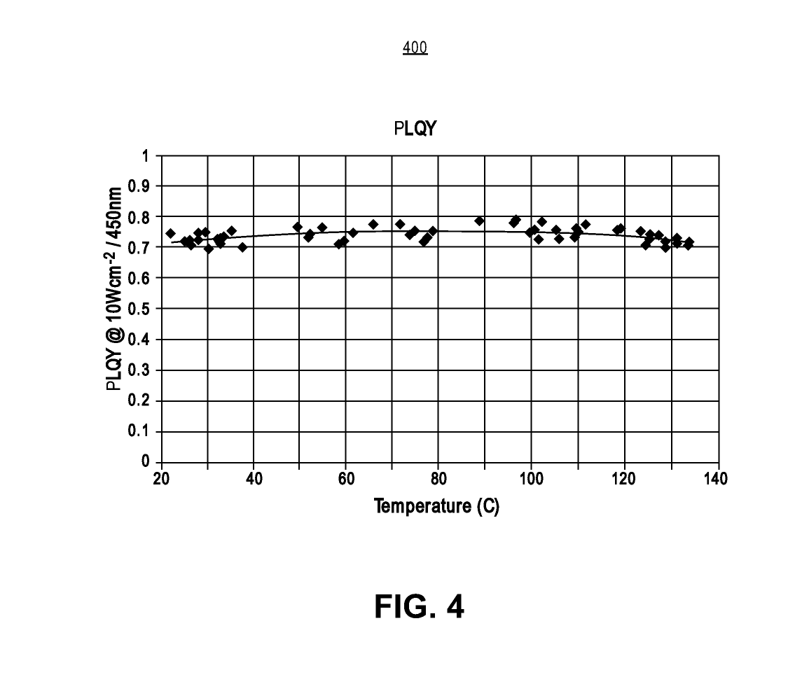

In an embodiment, a quantum dot structure is provided having an outermost smooth topography. A crystalline semiconductor coating is fabricated for the quantum dot structure and has an irregular outermost geometry. The irregular outermost geometry may have a topography that is lumpy, bumpy, spikey, or the like, i.e., that is not smooth. By foregoing a smooth outermost topography for the coating, a greater volume of material may be coated onto the underlying quantum dot. By enabling an increase in volume of a crystalline semiconductor coating for a quantum dot, the resulting structure may exhibit enhanced robustness against various conditions, as is described in association with FIGS. 4-6.

In an exemplary specific embodiment, the semiconductor material of the crystalline semiconductor coating is a crystalline coating of zinc sulfide (ZnS). A method of coating a quantum dot structure involves formation of a ZnS having an irregular distribution of between 0 and 4 added nanometers of material on a short axis of the quantum dot structure, and an irregular distribution of between 0 and 7 nanometers of material added on the long axis. Accordingly, in an embodiment, the crystalline semiconductor coating has a variable distribution of thickness along a single axis of the nanocrystalline shell. Although the distribution is irregular, in an embodiment, the entire foundational quantum dot structure is coated with the third crystalline semiconductor material. In one such embodiment, the coating provides an average of greater than approximately 3 nanometers of material in the width (coating the short axis) and an average of greater than approximately 5 nanometers of material in the length (coating the long axis). In an embodiment, reference to a zinc sulfide coating refers to a coating where the metal species of MS is predominantly zinc (Zn). However, secondary metals species, such as cadmium (Cd), may also be included.

In an exemplary synthesis, in accordance with an embodiment of the present invention, for operation (1) to a reaction flask (e.g., between 25 mL and 250 mL, but not excluding larger flask sizes), the following is added: (a) a magnetic stir bar, (b) solvent (trioctyl phosphine oxide (TOPO) is preferred, however, other high boiling solvents are also possible, such as octadecene), (c) a cadmium (Cd) precursor (cadmium oxide is preferred, but can instead or also include cadmium formate, cadmium acetate, cadmium nitrate, cadmium stearate, and other cadmium precursors; it is of note that dissociation temperatures of 280 degrees Celsius need only be achieved when cadmium oxide is used), (d) a zinc (Zn) precursor (preferably a highest purity zinc acetate dehydrate, 99.999% trace metals basis; however, this can instead or also include other zinc precursors at other purity levels, such as zinc acetate, zinc formate, zinc stearate, zinc oxide), (e) Ligand 1: a long-chain carboxylic acid (generally used is Oleic Acid, technical grade, 90%; however, other long chain carboxylic acids can be used), and (d) Ligand 2: and amine (generally used is octadecyl amine, but other long chain amines such as oleyl amine or alkyl chain of different lengths are also viable choices).

In operation (2) the reaction is equilibrated at approximately 120 degrees Celsius under flowing ultra-high purity (UHP) argon gas. The solvent will melt/liquefy and disperse other solids at approximately 60 degrees Celsius, so stirring is begun at this point and continued throughout the reaction. In one embodiment, stirring is performed at approximately 1200 RPM (i.e., to handle a large volume of material) but smaller scales can employed speeds as low as 800 RPM.

In operation (3), the mixture from (2) is degassed at approximately 120 degrees Celsius for a given time (e.g., approximately between 30 and 90 minutes, depending on the metal precursors involved).

In operation (4), the metal precursors are dissociated into metal-oleate forms. Temperatures approximately between 280 degrees Celsius and 310 degrees Celsius may be required if metal-oxide precursors are used which require dissociation to the metal-oleate form. However, this operation may be skipped if metal oxide precursors are not used, since equilibration at reaction temperature should facilitate formation of the Zn- and Cd-oleate forms).

In operation (5) the reaction mixture is equilibrated at a reaction temperature of approximately 235 degrees Celsius. Growth has been observed for some conditions as low as approximately 170 degrees Celsius and as high as approximately 270 degrees Celsius, but optimal conditional appear to be approximately 235 degrees Celsius.

In operation (6), a rapid injection of a mixture of (a) QDH (CdSe/CdS core/shell nanorods), and (b) 7.4 wt % sulfur: tri-octyl phosphate (TOP) stock solution into the mixture of (5) is performed.

In operation (7), coating growth is allowed to occur for approximately 4 hours and 45 minutes (with continued stirring, UHP argon flow, and a temperature maintained at the reaction temperature of operation (5).

In operation (8), after the growth period, slow cooling of the mixture to room temperature is performed with continued stirring and continued UHP argon flow.

In operation (9), at a temperature less than approximately 80 degrees Celsius, the mixture is exposed to air and solvent (e.g., toluene or cyclohexane) is injected. The mixture is allowed to recover while stirring under argon until the reaction solution has a temperature below approximately 25 degrees Celsius.

In operation (10), two precipitation/centrifugation cycles are performed using iso-propyl alcohol (IPA) and methanol (MeOH) as anti-solvents, and cyclohexane as a solvent to purify the materials. For larger scale reactions, centrifugation speeds are capped at approximately 4200 RPM based on the rotor capability. For smaller scales, centrifuge is performed at speeds up to approximately 9000 RPM (e.g., max capability of a particular rotor).

In operation (11), the final solid product dissolved is in an organic solvent (e.g., cyclohexane is preferred; other solvents are possible, such as hexane, toluene).

With reference to operations (1)-(11), in a particular embodiment, the following ratios are used during the semiconductor coating process: (a) Zn:Cd at a ratio of approximately 37:1, (b) Ligand 1:Ligand 2 at a ratio of approximately 10:1, (c) total ligand:total metal at a ratio of approximately 2.25:1, and (d) metal:sulfur at a ratio of approximately 1.26:1.

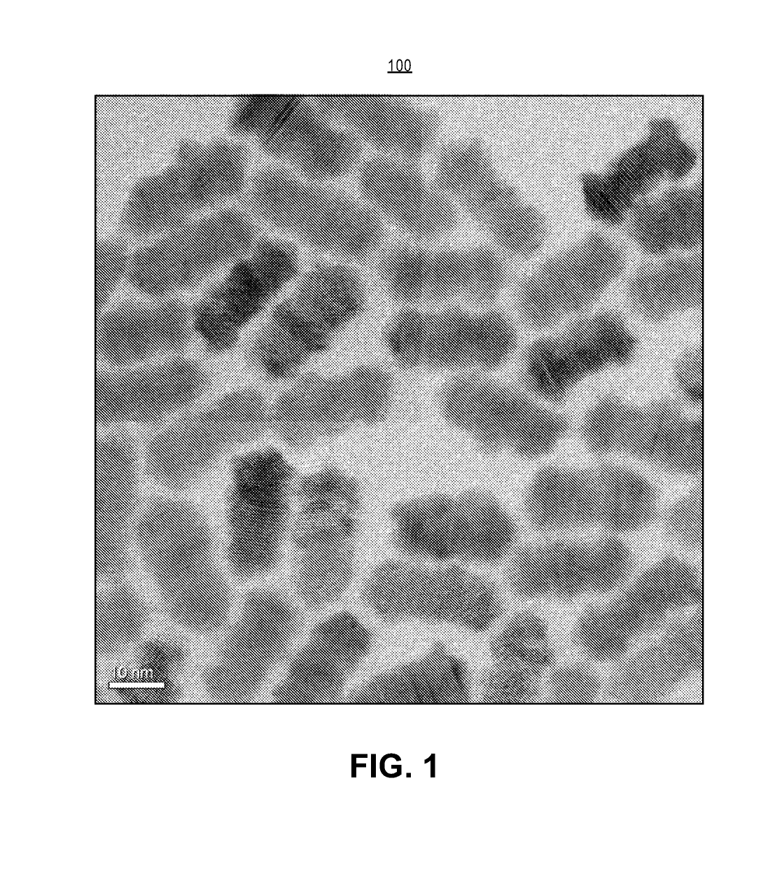

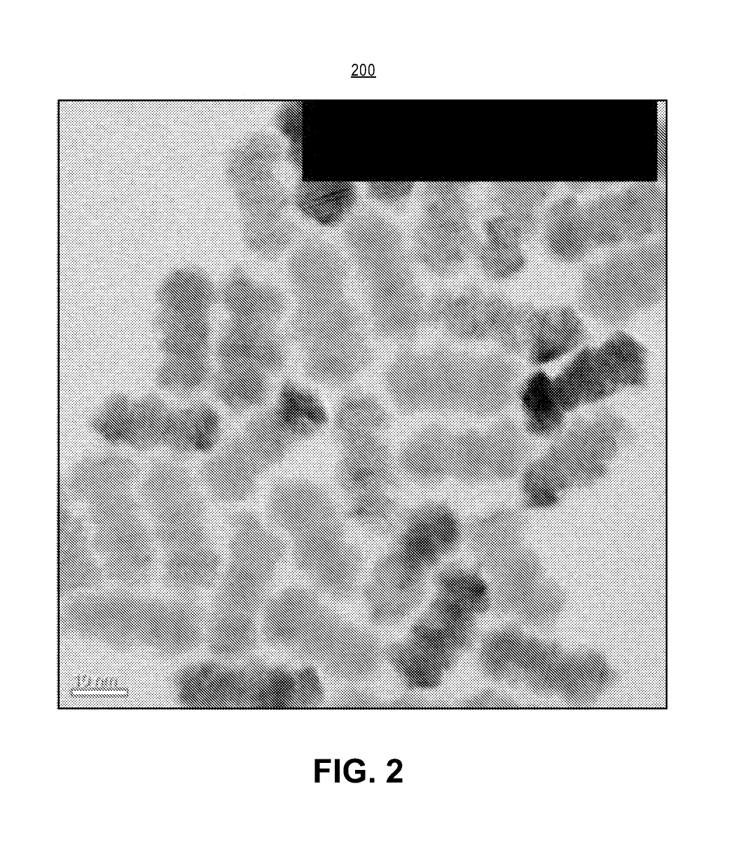

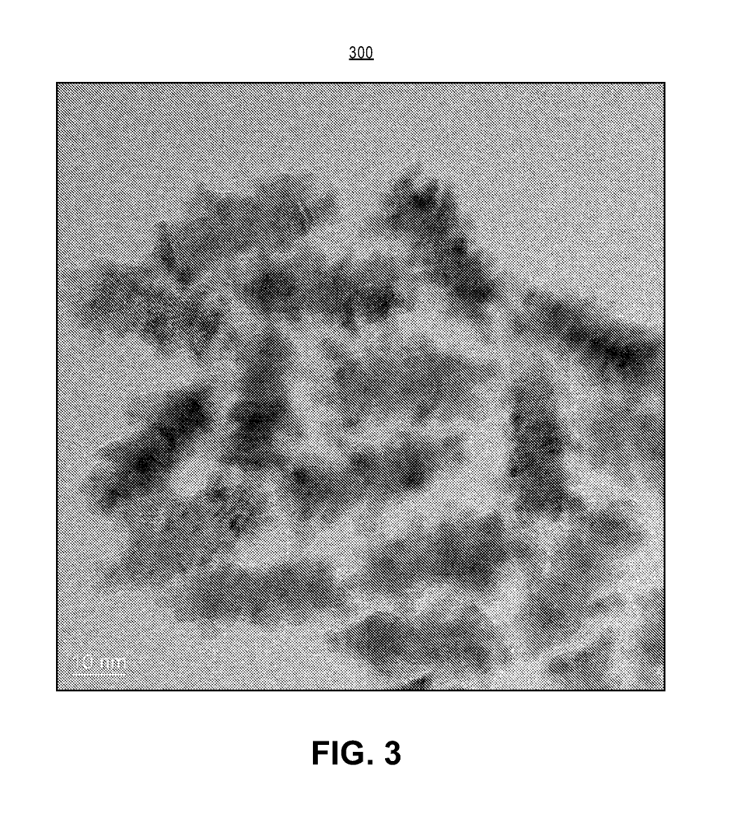

The resulting coated quantum dots having the high volume crystalline ZnS coating thereon have irregular outermost geometries, which can be described as bumpy, lumpy, spiky, etc. Thus, in an embodiment, an irregular outermost geometry of a crystalline semiconductor coating can be described as having has a topography such as lumpy, bumpy or spikey. FIGS. 1-3 are representative transmission electron microscope (TEM) images 100, 200, 300, respectively, showing the outer irregular coating grown on the quantum dot structures, in accordance with an embodiment of the present invention.

In accordance with an embodiment of the present invention, the addition of the above described ZnS crystalline semiconductor coating to a quantum dot provides an extra layer of protection which results in a higher, more reliable performance under conditions of high incident intensity, high operating temperatures, and humidity. As an example of rigorous temperature conditions, FIG. 4 is a plot 400 showing representative temperature performance for irregularly coated quantum dots. Referring to plot 400, the quantum yield is measured for films under 10 W/cm2 illumination at varying temperatures. Even for a temperature range of approximately 20-125 degrees Celsius, the photo-luminescent quantum yield (PLQY) is suitably steady across such changing conditions.

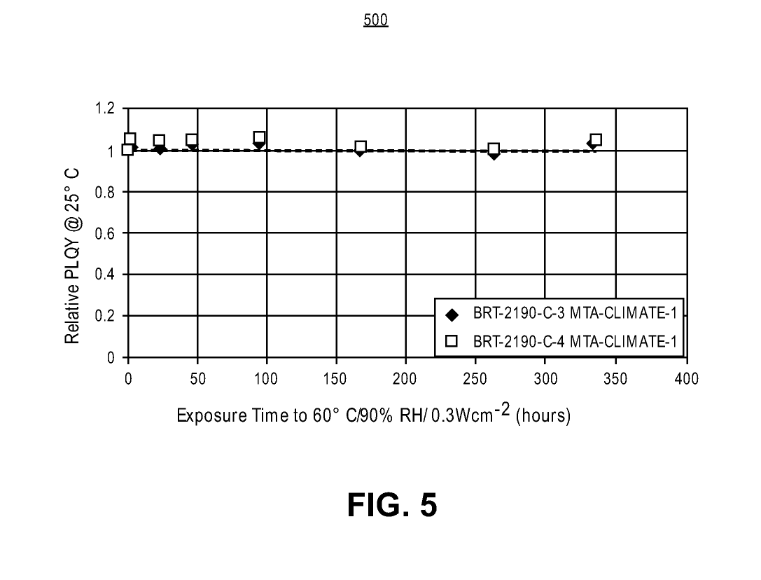

As an example of rigorous humidity conditions, FIG. 5 is a plot 500 showing representative climate chamber performance for irregularly coated quantum dots. Referring to plot 500, the quantum yield is measured for films having variable exposure to high relative humidity (RH). The films exhibit a photo-luminescent quantum yield (PLQY) is suitably steady for a variety of durations.

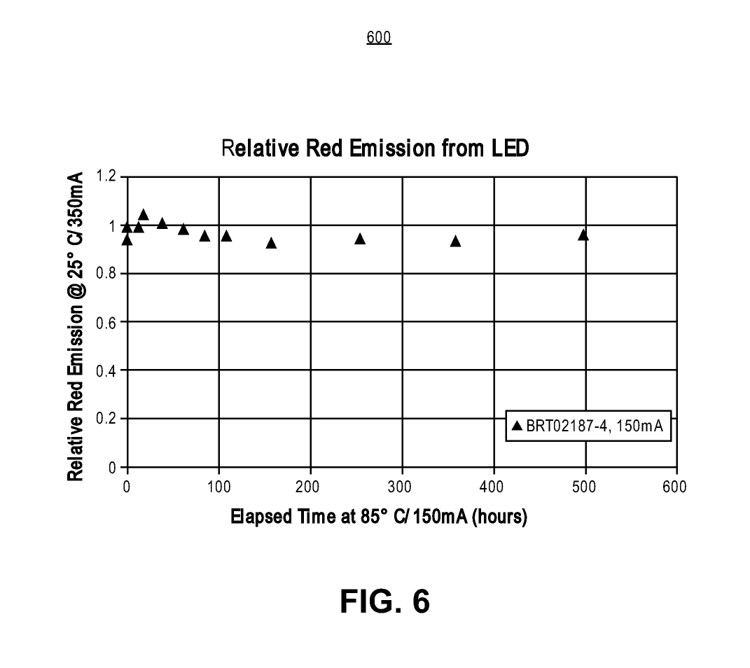

As an example of rigorous on-LED conditions, FIG. 6 is a plot 600 showing relative red emission from an LED for irregularly coated quantum dots. Referring to plot 600, the relative red emission is measured for films having variable elapsed time of use on an LED. The relative red emission is suitably steady for a variety of durations.

Referring again to FIGS. 1-6 and the above exemplary synthetic process flow, in accordance with embodiments of the present invention, a set of growth conditions can be employed to add a significant amount of ZnS material to a rod of a core/shell pairing in an unusual lumpy (or spiky, or bumpy) structural appearance, which are described herein as being irregular in morphology. The resulting irregularly coated quantum dots are high performance, environmentally stable quantum dots.

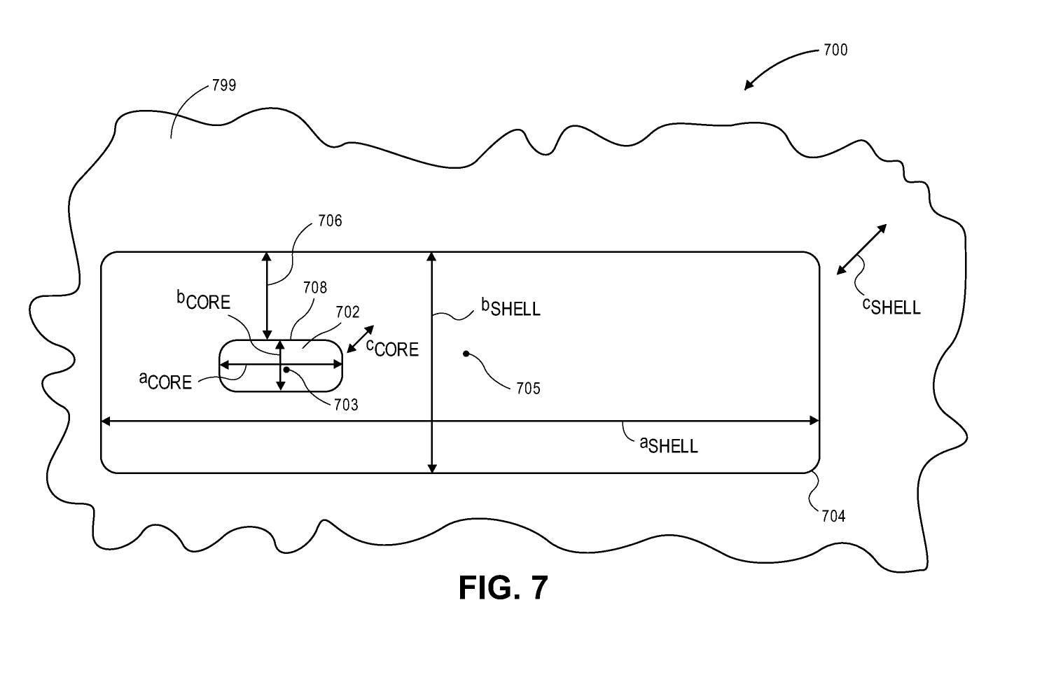

As described above, hetero-structure-based quantum dots may have an irregular semiconductor coating formed thereon. It is to be appreciated that the resulting structure having a third semiconductor layer thereon may also be referred to as a quantum dot heterostructure (QDH). For instances when description is intended to exclude the outer irregular coating, a hetero-structures may be referred to as a nano-crystalline core and nano-crystalline shell pairing. The nano-crystalline core and nano-crystalline shell pairing may have specific geometries suitable for performance optimization. In an example, several factors may be intertwined for establishing an optimized geometry for a quantum dot having a nano-crystalline core and nano-crystalline shell pairing. As a reference, FIG. 7 illustrates a schematic of a cross-sectional view of a nano-crystalline core and nano-crystalline shell pairing with an irregular crystalline semiconductor layer formed thereon, in accordance with an embodiment of the present invention.

Referring to FIG. 7, a semiconductor structure (e.g., a quantum dot structure) 700 includes a nano-crystalline core 702 surrounded by a nano-crystalline shell 704. The nano-crystalline core 702 has a length axis (_{aCORE}), a width axis (_{bCORE}) and a depth axis (_{cCORE}), the depth axis provided into and out of the plane shown in FIG. 7. Likewise, the nano-crystalline shell 704 has a length axis (_{aSHELL}), a width axis (_{bSHELL}) and a depth axis (_{cSHELL}), the depth axis provided into and out of the plane shown in FIG. 7. The nano-crystalline core 702 has a center 703 and the nano-crystalline shell 704 has a center 705. The nano-crystalline shell 704 surrounds the nano-crystalline core 702 in the b-axis direction by an amount 706, as is also depicted in FIG. 7.

In addition to material composition, the following are attributes of a quantum dot that may be tuned for optimization, with reference to the parameters provided in FIG. 7, in accordance with embodiments of the present invention. Nano-crystalline core 702 diameter (a, b or c) and aspect ratio (e.g., a/b) can be controlled for rough tuning for emission wavelength (a higher value for either providing increasingly red emission). A smaller overall nano-crystalline core provides a greater surface to volume ratio. The width of the nano-crystalline shell along 706 may be tuned for yield optimization and quantum confinement providing approaches to control red-shifting and mitigation of surface effects. However, strain considerations must be accounted for when optimizing the value of thickness 706.

The length (a_{SHELL}) of the shell is tunable to provide longer radiative decay times as well as increased light absorption. The overall aspect ratio of the structure 700 (e.g., the greater of a_{SHELL}/b_{SHELL} and a_{SHELL}/c_{SHELL}) may be tuned to directly impact PLQY. Meanwhile, overall surface/volume ratio for 700 may be kept relatively smaller to provide lower surface defects, provide higher photoluminescence, and limit self-absorption. Referring again to FIG. 7, the shell/core interface 708 may be tailored to avoid dislocations and strain sites. In one such embodiment, a high quality interface is obtained by tailoring one or more of injection temperature and mixing parameters, the use of surfactants, and control of the reactivity of precursors. The interface may also be alloyed to relieve strain.

In accordance with an embodiment of the present invention, a high PLQY quantum dot is based on a core/shell pairing using an anisotropic core. With reference again to FIG. 7, an anisotropic core is a core having one of the axes a_{CORE}, b_{CORE} or c_{CORE} different from one or both of the remaining axes. An aspect ratio of such an anisotropic core is determined by the longest of the axes a_{CORE}, b_{CORE} or c_{CORE} divided by the shortest of the axes a_{CORE}, b_{CORE} or c_{CORE} to provide a number greater than 1 (an isotropic core has an aspect ratio of 1). It is to be understood that the outer surface of an anisotropic core may have rounded or curved edges (e.g., as in an ellipsoid) or may be faceted (e.g., as in a stretched or elongated tetragonal or hexagonal prism) to provide an aspect ratio of greater than 1 (note that a sphere, a tetragonal prism, and a hexagonal prism are all considered to have an aspect ratio of 1 in keeping with embodiments of the present invention).

A workable range of aspect ratio for an anisotropic nano-crystalline core for a quantum dot may be selected for maximization of PLQY. For example, a core essentially isotropic may not provide advantages for increasing PLQY, while a core with too great an aspect ratio (e.g., 2 or greater) may present challenges synthetically and geometrically when forming a surrounding shell. Furthermore, embedding the core in a shell composed of a material different than the core may also be used enhance PLQY of a resulting quantum dot.

Accordingly, in an embodiment, a semiconductor structure includes an anisotropic nano-crystalline core composed of a first semiconductor material and having an aspect ratio between, but not including, 1.0 and 2.0. The semiconductor structure also includes a nano-crystalline shell composed of a second, different, semiconductor material at least partially surrounding the anisotropic nano-crystalline core. In one such embodiment, the aspect ratio of the anisotropic nano-crystalline core is approximately in the range of 1.01-1.2 and, in a particular embodiment, is approximately in the range of 1.1-1.2. In the case of rounded edges, then, the nano-crystalline core may be substantially, but not perfectly, spherical. However, the nano-crystalline core may instead be faceted. In an embodiment, the anisotropic nano-crystalline core is disposed in an asymmetric orientation with respect to the nano-crystalline shell, as described in greater detail in the example below. In other embodiments, however, the anisotropic nano-crystalline core is disposed in an on-axis (centered) with respect to the nano-crystalline shell.

Another consideration for maximization of PLQY in a quantum dot structure is to provide an asymmetric orientation of the core within a surrounding shell. For example, referring again to FIG. 7, the center 703 of the core 702 may be misaligned with (e.g., have a different spatial point than) the center 705 of the shell 704. In an embodiment, a semiconductor structure includes an anisotropic nano-crystalline core composed of a first semiconductor material. The semiconductor structure also includes a nano-crystalline shell composed of a second, different, semiconductor material at least partially surrounding the anisotropic nano-crystalline core. The anisotropic nano-crystalline core is disposed in an asymmetric orientation with respect to the nano-crystalline shell. In one such embodiment, the nano-crystalline shell has a long axis (e.g., a_{SHELL}), and the anisotropic nano-crystalline core is disposed off-center along the long axis. In another such embodiment, the nano-crystalline shell has a short axis (e.g., b_{SHELL}), and the anisotropic nano-crystalline core is disposed off-center along the short axis. In yet another embodiment, however, the nano-crystalline shell has a long axis (e.g., a_{SHELL}) and a short axis (e.g., b_{SHELL}), and the anisotropic nano-crystalline core is disposed off-center along both the long and short axes.

With reference to the above described nano-crystalline core and nano-crystalline shell pairings, in an embodiment, the nano-crystalline shell completely surrounds the anisotropic nano-crystalline core. In an alternative embodiment, however, the nano-crystalline shell only partially surrounds the anisotropic nano-crystalline core, exposing a portion of the anisotropic nano-crystalline core, e.g., as in a tetrapod geometry or arrangement. In an embodiment, the nano-crystalline shell is an anisotropic nano-crystalline shell, such as a nano-rod, that surrounds the anisotropic nano-crystalline core at an interface between the anisotropic nano-crystalline shell and the anisotropic nano-crystalline core. The anisotropic nano-crystalline shell passivates or reduces trap states at the interface. The anisotropic nano-crystalline shell may also, or instead, deactivate trap states at the interface.

With reference again to the above described nano-crystalline core and nano-crystalline shell pairings, in an embodiment, the first and second semiconductor materials (core and shell, respectively) are each materials such as, but not limited to, Group II-VI materials (where the group II species could include species from Groups II (e.g., magnesium) or XII of the periodic table), Group III-V materials, Group IV-VI materials, Group I-III-VI materials, or Group II-IV-VI materials and, in one embodiment, are mono-crystalline. In one such embodiment, the first and second semiconductor materials are both Group II-VI materials, the first semiconductor material is cadmium selenide (CdSe), and the second semiconductor material is one such as, but not limited to, cadmium sulfide (CdS), zinc sulfide (ZnS), or zinc selenide (ZnSe).

With reference again to the above described nano-crystalline core and nano-crystalline shell pairings, in an embodiment, the semiconductor structure (i.e., the core/shell pairing in total) has an aspect ratio approximately in the range of 1.5-10 and, 3-6 in a particular embodiment. In an embodiment, the nano-crystalline shell has a long axis and a short axis. The long axis has a length approximately in the range of 5-40 nanometers. The short axis has a length approximately in the range of 1-5 nanometers greater than a diameter of the anisotropic nano-crystalline core parallel with the short axis of the nano-crystalline shell. In a specific such embodiment, the anisotropic nano-crystalline core has a diameter approximately in the range of 2-5 nanometers. The thickness of the nano-crystalline shell on the anisotropic nano-crystalline core along a short axis of the nano-crystalline shell is approximately in the range of 1-5 nanometers of the second semiconductor material.

With reference again to the above described nano-crystalline core and nano-crystalline shell pairings, in an embodiment, the anisotropic nano-crystalline core and the nano-crystalline shell form a quantum dot. In one such embodiment, the quantum dot has a photoluminescence quantum yield (PLQY) of at least 90%. Emission from the quantum dot may be mostly, or entirely, from the nano-crystalline core. For example, in an embodiment, emission from the anisotropic nano-crystalline core is at least approximately 75% of the total emission from the quantum dot. An absorption spectrum and an emission spectrum of the quantum dot may be essentially non-overlapping. For example, in an embodiment, an absorbance ratio of the quantum dot based on absorbance at 400 nanometers versus absorbance at an exciton peak for the quantum dot is approximately in the range of 5-35.

Referring again to FIG. 7, in accordance with an embodiment of the present invention, the semiconductor structure further includes a crystalline semiconductor coating 799 completely surrounding the nano-crystalline shell 704. The crystalline semiconductor coating 799 is composed of a third semiconductor material different from the first and second semiconductor materials. In a particular such embodiment, the first semiconductor material is cadmium selenide (CdSe), the second semiconductor material is cadmium sulfide (CdS), and the third semiconductor material is zinc sulfide (ZnS). In one such embodiment, the ZnS layer may include a minority portion of cadmium (e.g., substantially less cadmium than Zn) and be referred to as a ZnS coating. In other embodiments, however, the third semiconductor material is the same as one of the first and second semiconductor materials. Additionally, it is to be appreciated that in more general embodiments, such a lumpy, bumpy or spikey coating can be added to any suitable “smooth” core shells including quantum dots having three or more layers, so long as the outer surface of the starting QD material is smooth, or is said to have a smooth topography.

In an embodiment, as described above, the crystalline semiconductor coating 799 is irregular in form. That is, the crystalline semiconductor coating 799 may be described as lumpy, bumpy, spiky or the like, referring to the non-smooth (rough) exterior of the crystalline semiconductor coating 799 (versus, say, a smooth rod structure). The irregular aspect of the coating crystalline semiconductor coating 799 leaves a variable thickness of the third semiconductor material along any one of the axis of the nano-crystalline shell 704. For example, in one embodiment, although variable, the thickness of the semiconductor coating 799 formed along the long surface (along the a-shell axis) is greater than approximately 3 nanometers on average. Meanwhile, the thickness of the semiconductor coating 799 formed along the short surface (along the b-shell axis) at the ends of the nano-crystalline shell 704 is greater than approximately 5 nanometers on average.

It is also to be appreciated that, although already a variable thickness coating, the nano-crystalline shell 704 may be formed with or without alignment to a global center of the crystalline semiconductor coating 799. In one embodiment, then, the nano-crystalline shell 704 is formed centered to a global center of the crystalline semiconductor coating 799. In another embodiment, the nano-crystalline shell 704 is formed off-set from a global center of the crystalline semiconductor coating 799.

In an embodiment, a quantum dot based on the above described nano-crystalline core and nano-crystalline shell pairings is a down-converting quantum dot. However, in an alternative embodiment, the quantum dot is an up-shifting quantum dot. In either case, a lighting apparatus may include a light emitting diode and a plurality of quantum dots such as those described above. The quantum dots may be applied proximal to the LED and provide down-shifting or up-shifting of light emitted from the LED. Thus, semiconductor structures according to the present invention may be advantageously used in solid state lighting. The visible spectrum includes light of different colors having wavelengths between about 380 nm and about 780 nm that are visible to the human eye. An LED will emit a UV or blue light which is down-converted (or up-shifted) by semiconductor structures described herein. Any suitable ratio of emission color from the semiconductor structures may be used in devices of the present invention. LED devices according to embodiments of the present invention may have incorporated therein sufficient quantity of semiconductor structures (e.g., quantum dots) described herein capable of down-converting any available blue light to red, green, yellow, orange, blue, indigo, violet or other color. These structures may also be used to downconvert or upconvert lower energy light (green, yellow, etc) from LED devices, as long as the excitation light produces emission from the structures.

Referring to FIGS. 1-3 and 7, although not depicted, the structure 700 may further include an insulator coating surrounding and encapsulating the quantum dots having the irregular crystalline semiconductor coating thereon. In one such embodiment, the insulator coating is composed of an amorphous material such as, but not limited to, silica (SiOₓ), titanium oxide (TiOₓ), zirconium oxide (ZrOₓ), alumina (AlOₓ), or hafnia (HfOₓ). In an embodiment, insulator-coated structures based on structure 700 are referred to in their entirety as quantum dot structures for convenience. For example, the resulting structures, with our without an insulator coating may be used as down-converting quantum dots or up-shifting quantum dots and are referred to accordingly.

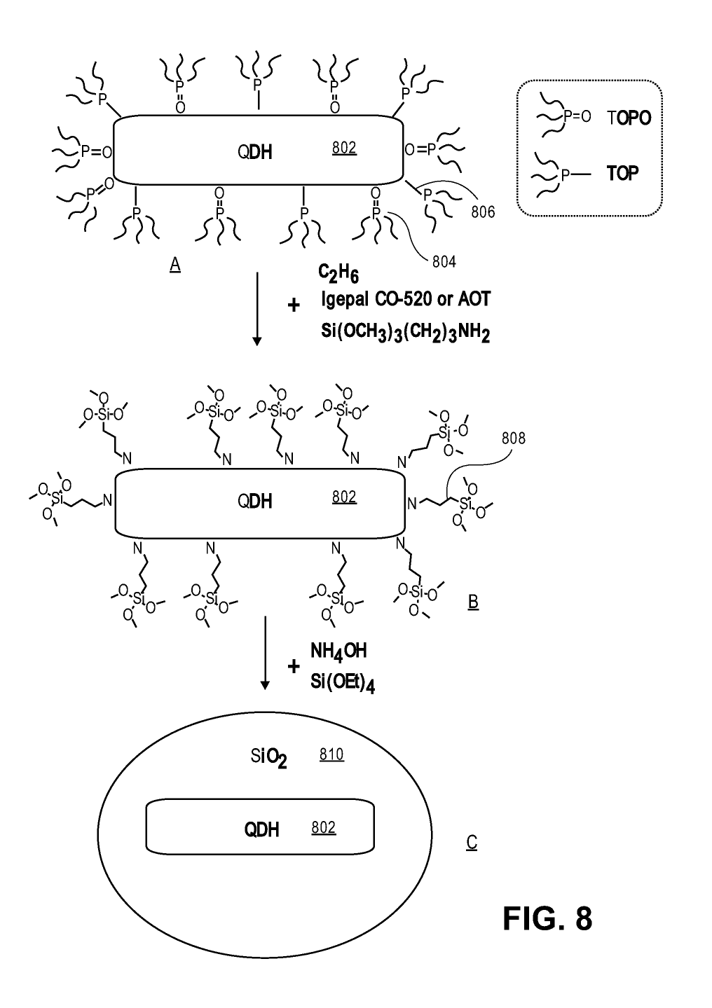

The above described insulator coating may be formed to encapsulate a quantum dot using a reverse micelle process. For example, FIG. 8 illustrates operations in a reverse micelle approach to insulating a semiconductor structure (e.g., where the semiconductor structure is a quantum dot having an irregular crystalline semiconductor coating thereon), in accordance with an embodiment of the present invention. Referring to part A of FIG. 8, a quantum dot hetero-structure (QDH) 802 (e.g., a nano-crystalline core/shell pairing having an irregular crystalline semiconductor coating thereon) has attached thereto a plurality of TOPO ligands 804 and TOP ligands 806. It is to be appreciated that other approaches may work as well, such as surface ligand exchange. For example the ligand can be selected from phosphonic acids, oleic acids, etc, before the silica is added. Referring to part B, the plurality of TOPO ligands 804 and TOP ligands 806 are exchanged with a plurality of Si(OCH₃)₃(CH₂)₃NH₂ ligands 808. The structure of part B is then reacted with TEOS (Si(OEt)₄) and ammonium hydroxide (NH₄OH) to form a silica coating 810 surrounding the QDH 802, as depicted in part C of FIG. 8.

In another aspect, a polymer matrix composition is applied to a lighting device to provide a layer having a dispersion of semiconductor structures therein for inclusion in the lighting device. In one embodiment, the dispersion of semiconductor structures is a dispersion of quantum dots such as those described above in association with FIGS. 1-3, 7 and 8.

In a first exemplary embodiment, a method of applying a light-conversion layer to a surface of a light-emitting diode (LED) includes first, separately, forming a polymer matrix from a mixture of quantum dots. The resulting polymer matrix includes a dispersion of the quantum dots therein and is then applied to the surface of the LED. In one such embodiment, applying the polymer matrix to the surface of the LED involves using a technique such as, but not limited to, spraying, dip-coating, spin-coating, or drop-casting. The polymer matrix can be cured with ultra-violet (UV) light exposure or heating, in one embodiment. It is to be appreciated that the polymer matrix having the dispersion of quantum dots therein can be applied to discrete LED devices or, in another embodiment, prior to dicing the LEDs from a wafer having a plurality of LED dies. In the latter case, application of the polymer matrix or matrix can involve uniform distribution across the wafer prior to dicing the wafer.

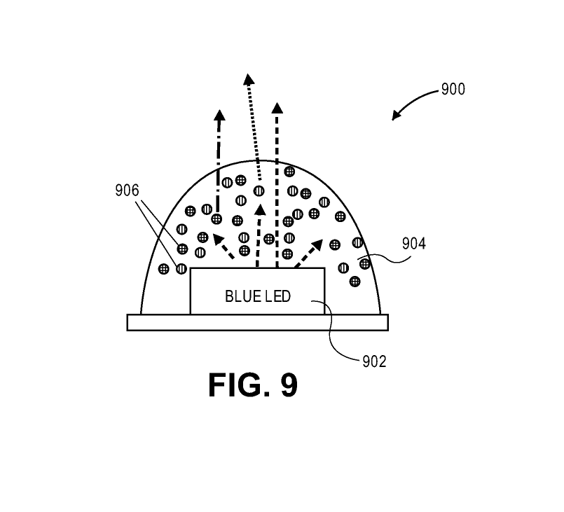

With respect to illustrating the above concepts in a resulting device configuration, FIG. 9 illustrates a lighting device 900. Device 900 has a blue LED 902 with a polymer matrix layer 904 having a dispersion of irregularly coated quantum dots 906 therein, in accordance with an embodiment of the present invention. Devices 900 may be used to produce “cold” or “warm” white light. In one embodiment, the device 900 has little to no wasted energy since there is little to no emission in the IR regime. In a specific such embodiment, the use of a polymer matrix layer having a composition with a dispersion of anisotropic quantum dots therein enables greater than approximately 40% lm/W gains versus the use of conventional phosphors. Increased efficacy may thus be achieved, meaning increased luminous efficacy based on lumens (perceived light brightness) per watt electrical power. Accordingly, down converter efficiency and spectral overlap may be improved with the use of a dispersion of quantum dots to achieve efficiency gains in lighting and display. In an additional embodiment, a conventional phosphor is also included in the polymer matrix composition, along with the dispersion of quantum dots 906.

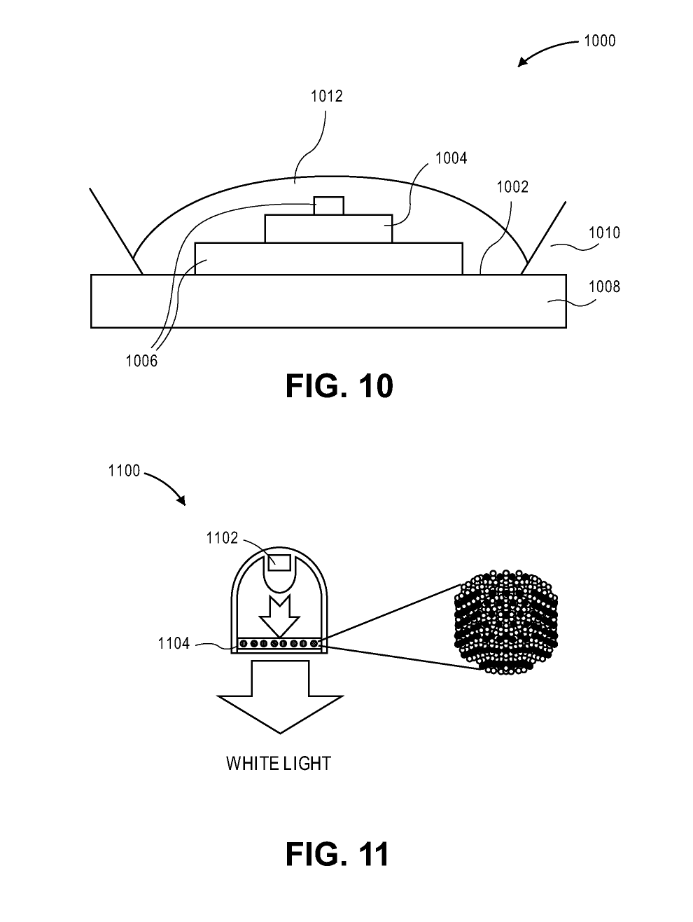

Different approaches may be used to provide a quantum dot layer in a lighting device. In an example, FIG. 10 illustrates a cross-sectional view of a lighting device 1000 with a layer having a polymer matrix composition with a dispersion of irregularly coated quantum dots therein, in accordance with an embodiment of the present invention. Referring to FIG. 10, a blue LED structure 1002 includes a die 1004, such as an InGaN die, and electrodes 1006. The blue LED structure 1002 is disposed on a coating or supporting surface 1008 and housed within a protective and/or reflective structure 1010. A polymer matrix layer 1012 is formed over the blue LED structure 1002 and within the protective and/or reflective structure 1010. The polymer matrix layer 1012 has a composition including a dispersion of quantum dots or a combination of a dispersion of quantum dots and conventional phosphors. Although not depicted, the protective and/or reflective structure 1010 can be extended upwards, well above the matrix layer 1012, to provide a “cup” configuration.

Although described herein as applicable for on-chip applications, polymer matrix compositions may also be used as remote layers. In an example, FIG. 11 illustrates a cross-sectional view of a lighting device 1100 with a polymer matrix layer having a composition with a dispersion of irregularly coated quantum dots therein, in accordance with another embodiment of the present invention. Referring to FIG. 11, the lighting device 1100 includes a blue LED structure 1102. A quantum dot down converter screen 1104 is positioned somewhat remotely from the blue LED structure 1102. The quantum dot down converter screen 1104 includes a polymer matrix layer with a composition having a dispersion of quantum dots therein, e.g., of varying color, or a combination of a dispersion of quantum dots and conventional phosphors. In one embodiment, the device 1100 can be used to generate white light, as depicted in FIG. 11.

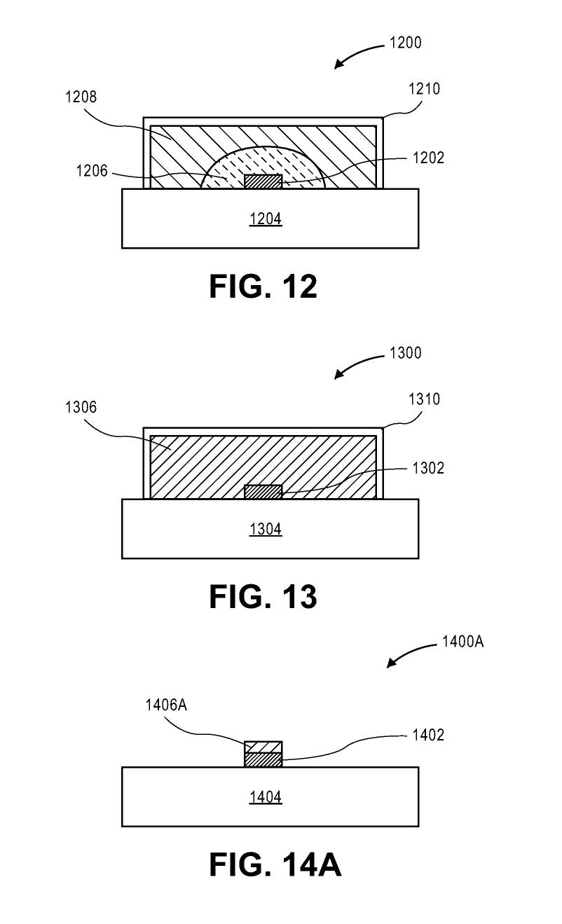

In another example, FIG. 12 illustrates a cross-sectional view of a lighting device 1200 with a layer having a polymer matrix composition with a dispersion of irregularly coated quantum dots therein, in accordance with another embodiment of the present invention. Referring to FIG. 12, the lighting device 1200 includes a blue LED structure 1202 supported on a substrate 1204 which may house a portion of the electrical components of the blue LED structure 1202. A first conversion layer 1206 has a polymer matrix composition that includes a dispersion of red-light emitting anisotropic quantum dots therein. A second conversion layer 1208 has a second polymer matrix composition that includes a dispersion of quantum dots or green or yellow phosphors or a combination thereof (e.g., yttrium aluminum garnet, YAG phosphors) therein. Optionally, a sealing layer 1210 may be formed over the second conversion layer 1208, as depicted in FIG. 12. In one embodiment, the device 1200 can be used to generate white light.

In another example, FIG. 13 illustrates a cross-sectional view of a lighting device 1300 with a layer having a polymer matrix composition with a dispersion of irregularly coated quantum dots therein, in accordance with another embodiment of the present invention. Referring to FIG. 13, the lighting device 1300 includes a blue LED structure 1302 supported on a substrate 1304 which may house a portion of the electrical components of the blue LED structure 1302. A single conversion layer 1306 has a polymer matrix composition that includes a dispersion of red-light emitting anisotropic quantum dots in combination with a dispersion of green quantum dots or green and/or yellow phosphors therein. Optionally, a sealing layer 1310 may be formed over the single conversion layer 1306, as depicted in FIG. 13. In one embodiment, the device 1300 can be used to generate white light.

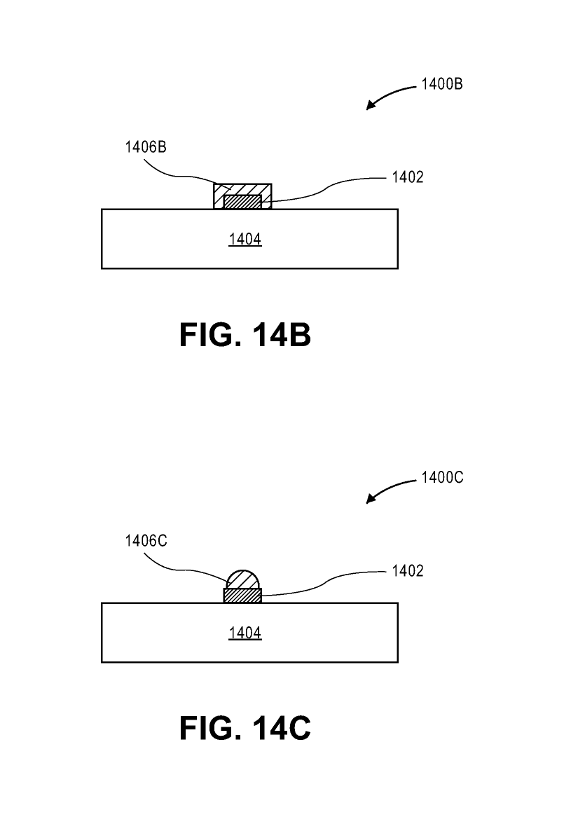

In additional examples, FIGS. 14A-14C illustrate cross-sectional views of various configurations for lighting devices 1400A-1400C with a layer having a polymer matrix composition with a dispersion of irregularly coated quantum dots therein, respectively, in accordance with another embodiment of the present invention. Referring to FIGS. 14A-14C, the lighting devices 1400A-1400C each include a blue LED structure 1402 supported on a substrate 1404 which may house a portion of the electrical components of the blue LED structure 1402. A conversion layer 1406A-1406C, respectively, has a polymer matrix composition that includes a dispersion of one or more light-emitting color types of quantum dots therein. Referring to FIG. 1400A specifically, the conversion layer 1406A is disposed as a thin layer only on the top surface of the blue LED structure 1402. Referring to FIG. 1400B specifically, the conversion layer 1406B is disposed as a thin layer conformal with all exposed surfaces of the blue LED structure 1402. Referring to FIG. 1400C specifically, the conversion layer 1406C is disposed as a “bulb” only on the top surface of the blue LED structure 1402. In the above examples (e.g., FIGS. 9-13 and 14A-14C), although use with a blue LED is emphasized, it is to be understood that a layer having a composition with a dispersion of irregularly coated quantum dots therein can be used with other light sources as well, including LEDs other than blue LEDs.

Thus, irregular large volume semiconductor coatings for quantum dots (QDs) and the resulting quantum dot materials have been disclosed.

1. A semiconductor structure, comprising:
a quantum dot structure having an outermost surface; and
a crystalline semiconductor coating disposed on and completely surrounding the outermost surface of the quantum dot structure, and having an irregular outermost geometry.

2. The semiconductor structure of claim 1, wherein the outermost surface of the quantum dot structure has a smooth topography.

3. The semiconductor structure of claim 1, wherein the crystalline semiconductor coating has a variable distribution of thickness along a single axis of the quantum dot structure.

4. The semiconductor structure of claim 1, wherein the irregular outermost geometry of the crystalline semiconductor coating has a topography selected from the group consisting of lumpy, bumpy and spikey.

5. The semiconductor structure of claim 1, wherein the crystalline semiconductor coating is a zinc sulfide (ZnS) layer that includes a minority portion of cadmium.

6. The semiconductor structure of claim 1, wherein the crystalline semiconductor coating has a thickness of greater than approximately 3 nanometers along a long surface of the quantum dot structure.

7. The semiconductor structure of claim 6, wherein the crystalline semiconductor coating has a thickness of greater than approximately 5 nanometers along a short surface of the quantum dot structure.

8. (canceled)

9. (canceled)

10. The semiconductor structure of claim 1,
wherein the quantum dot structure comprises:
a nanocrystalline core of a first semiconductor material; and
a nanocrystalline shell of a second semiconductor material different from the first semiconductor material, the nanocrystalline shell disposed on and surrounding the nanocrystalline core; and
wherein the crystalline semiconductor coating comprises:
a crystalline semiconductor coating of a third semiconductor material different from the first and second semiconductor materials, the crystalline semiconductor coating disposed on and completely surrounding the nanocrystalline shell, and having the irregular outermost geometry.

11. (canceled)

12. (canceled)

13. The semiconductor structure of claim 10, wherein the first semiconductor material is cadmium selenide (CdSe), the second semiconductor material is cadmium sulfide (CdS), and the third semiconductor material is zinc sulfide (ZnS).

14-34. (canceled)

35. A lighting apparatus, comprising:
a substrate;
a light emitting diode disposed on the substrate; and
a light conversion layer disposed above the light emitting diode, the light conversion layer comprising a plurality of quantum dots, each quantum dot comprising:
a nanocrystalline core of a first semiconductor material;
a nanocrytsalline shell of a second semiconductor material different from the first semiconductor material, the nanocrystalline shell disposed on and surrounding the nanocrystalline core; and
a crystalline semiconductor coating of a third semiconductor material different from the first and second semiconductor materials, the crystalline semiconductor coating disposed on and completely surrounding the nanocrystalline shell, and having an irregular outermost geometry

36. The lighting apparatus of claim 35, wherein, for each quantum dot, the first semiconductor material is cadmium selenide (CdSe), the second semiconductor material is cadmium sulfide (CdS), and the third semiconductor material is zinc sulfide (ZnS).

37. The lighting apparatus of claim 35, wherein, for each quantum dot, the crystalline semiconductor coating is a zinc sulfide (ZnS) layer that includes a minority portion of cadmium.

38. The lighting apparatus of claim 35, wherein, for each quantum dot, the crystalline semiconductor coating has a thickness of greater than approximately 3 nanometers along a long surface of the nanocrystalline shell and a thickness of greater than approximately 5 nanometers along a short surface of the nanocrystalline shell.

39-41. (canceled)

42. The lighting apparatus of claim 35, wherein the light emitting diode is a UV or visible spectrum light emitting diode, and wherein the light conversion layer is a down- or up-shifting layer.

43. The lighting apparatus of claim 42, wherein the light emitting diode is a blue light emitting diode, and wherein the light conversion layer is a down-shifting layer.

44. The lighting apparatus of claim 35, wherein the quantum dots vary in size and emission color, and wherein the light conversion layer is to provide white light.

45-47. (canceled)

48. The lighting apparatus of claim 35, wherein the light conversion layer comprises a combination of red quantum dots with yellow phosphors, green phosphors, or both.

49-51. (canceled)

52. The lighting apparatus of claim 35, wherein the light conversion layer is disposed on the light emitting diode.

53. The lighting apparatus of claim 35, wherein the light conversion layer is situated remotely from the light emitting diode.

54. (canceled)

55. The lighting apparatus of claim 35, further comprising a housing structure; and wherein the substrate and the light emitting diode are supported within the housing structure.
